(19) United States
(12) Patent Application Publication
(10) Pub. No.: US 2022/0104343 A1
(43) Pub. Date: Mar. 31, 2022

(54) STRETCHABLE ELECTRONIC DEVICE AND METHOD FOR MANUFACTURING THE SAME

(71) Applicant: ELECTRONICS AND TELECOMMUNICATIONS RESEARCH INSTITUTE, Daejeon (KR)

(72) Inventors: Ji-Young OH, Daejeon (KR); Seung Youl KANG, Daejeon (KR); Sujung KIM, Daejeon (KR); Chan Woo PARK, Daejeon (KR); Himchan OH, Daejeon (KR); Jae-Eun PI, Daejeon (KR); Chi-Sun HWANG, Daejeon (KR)

(21) Appl. No.: 17/459,815

(22) Filed: Aug. 27, 2021

(30) Foreign Application Priority Data
Sep. 28, 2020 (KR) 10-2020-0125827
Jul. 13, 2021 (KR) 10-2021-0091397

(51) Int. Cl. H05K 1/02; H05K 1/11; H01L 23/00; H01L 23/498; H05K 3/12; H01L 21/48

(52) U.S. Cl. CPC H05K 1/0283; H05K 2201/10166; H01L 24/32; H01L 23/4985; H05K 3/12; H01L 24/27; H01L 21/4867; H05K 2201/09445; H01L 2924/12041; H01L 2224/32104; H01L 2224/32227; H01L 2224/32237; H01L 2224/32013; H01L 2224/2731; H05K 2201/10106; H05K 1/111

(57) ABSTRACT

Provided are a stretchable electronic device and a method for manufacturing the same. The stretchable electronic device includes lines having lower pads, a chip provided on the lower pads and having first upper pads, which are wider than the lower pads, and an adhesive layer provided outside the lower pads or between the lower pads and bonded to the first upper pads.

### CROSS-REFERENCE TO RELATED APPLICATIONS

This U.S. non-provisional patent application claims priority under 35 U.S.C. § 119 of Korean Patent Application No. 10-2020-0125827, filed on Sep. 28, 2020, and No. 10-2021-0091397, Jul. 13, 2021, the entire contents of which are hereby incorporated by reference.

### BACKGROUND

The present disclosure herein relates to an electronic device and a method for manufacturing the same, and more particularly, to a stretchable electronic device and a method for manufacturing the same.

Recently, attention has been focused on stretchable and wearable electronic devices that are capable of being attached to the human body. In addition, many studies are being conducted on the stretchable and wearable electronic devices. A general wearable electronic device may include a semiconductor device having excellent electrical characteristics. However, a general wearable electronic device may have a disadvantage in that electrical performance decreases due to a difference in mechanical stress between a stretchable substrate and a semiconductor device.

When a bonding pad has a height different from that of an upper surface of the stretchable substrate, a chip is provided on a solder ball on the bonding pad. Thereafter, the chip is bonded to the bonding pad through a high temperature reflow process. The high temperature reflow process may damage the stretchable electronic device Also, the high temperature reflow process causes cracks and stress between the chip and the bonding pad. Furthermore, the high temperature reflow process may cause deformation of the stretchable electronic device.

In addition, when FPCB bonding is performed, the stretchable substrate is deformed due to a high-temperature and high-pressure process for bonding an ACF film, and as a result, in the case of the stretchable electronic device, it is difficult to perform the FPCB bonding.

### SUMMARY

The present disclosure provides a stretchable electronic device in which a chip is capable of being easily replaced.

The present disclosure also provides a stretchable electronic device in which a chip is capable of being stably bonded on a stretchable substrate.

The present disclosure also provides a method for manufacturing a stretchable electronic device, which is capable of omitting a reflow process by simultaneously performing mounting and bonding of the chip.

An embodiment of the inventive concept provides a stretchable electronic device. The stretchable electronic device includes: lines having lower pads; a chip provided on the lower pads and having first upper pads, which are wider than the lower pads; and an adhesive layer provided outside the lower pads or between the lower pads and bonded to the first upper pads.

In an embodiment, the stretchable electronic device may further include a stretchable substrate in which the lines and the adhesive layer are mounted.

In an embodiment, the stretchable electronic device may further include a lower plastic layer provided in the stretchable substrate below the lines and the lower pads.

In an embodiment, the stretchable electronic device may further include a first lower fixing layer provided in the stretchable substrate to surround the adhesive layer, the lower pads, and the upper plastic layer.

In an embodiment, the stretchable electronic device may further include a second lower fixing layer configured to surround the first lower fixing layer and provided in the stretchable substrate.

In an embodiment, each of the first lower fixing layer and the second lower fixing layer may include PDMS.

In an embodiment, the stretchable electronic device may further include a thin film transistor provided in the lower plate layer and connected to the lines.

In an embodiment, each of the stretchable substrate and the adhesive layer may include a silicon compound.

In an embodiment, the stretchable electronic device may further include an upper fixing layer configured to cover the chip.

In an embodiment, the stretchable electronic device may further include a flexible printed circuit board disposed outside the chip and having second upper pads provided on the lower pads.

In an embodiment of the inventive concept, a stretchable electronic device includes: a stretchable substrate; lines disposed on the stretchable substrate and having lower pads; a lower fixing layer configured to surround the lower pads and spaced apart from the lower pads; an adhesive layer provided outside the lower pads or between the lower pads within the lower fixing layer; and a chip having first upper pads aligned on the adhesive layer, the chip provided on the adhesive layer and the lower pads.

In an embodiment, the stretchable electronic device may further include: a thin film transistor provided in the lower plate layer and connected to the lines; and a flexible printed circuit board having second upper pads aligned on the adhesive layer, the second upper pads provided on the lower pads.

In an embodiment of the inventive concept, a method for manufacturing a flexible electronic device includes: forming lines having lower pads on a dummy substrate; bonding a pickup film on the lines; removing the dummy substrate; forming an adhesive layer on the pickup film outside the lower pads; removing the pickup film; and bonding a chip having first upper pads, which are wider than the lower pads and bonded to the adhesive layer.

In an embodiment, the method may further include: forming a first lower fixing layer on the pickup film between the lower pads and the adhesive layer; and a second lower fixing layer on the first lower fixing layer and the adhesive layer.

In an embodiment, the method may further include forming a flexible substrate on the second lower fixing layer.

In an embodiment, each of the stretchable substrate and the adhesive layer may include a silicon compound formed through a dripping method or printing method.

In an embodiment, the method may further include forming an upper fixing layer on the chip and the stretchable substrate outside the chip.

In an embodiment, each of the first lower fixing layer and the second lower fixing layer may include PDMS formed through a printing method.

In an embodiment, the method may further include forming a lower plastic layer between the dummy substrate and the lines.

In an embodiment, the method may further include forming an upper plastic layer on the lines outside the adhesive layer.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a flowchart illustrating a method for manufacturing a stretchable electronic device according to an embodiment of the inventive concept;

FIGS. 2 to 13 are cross-sectional view illustrating processes of the stretchable electronic device according to an embodiment of the inventive concept;

FIG. 14 is a plan view illustrating an example of lines of FIG. 4;

FIG. 15 is a cross-sectional view illustrating an example of an adhesive layer of FIG. 11;

FIG. 16 is a cross-sectional view illustrating an example of the adhesive layer of FIG. 11;

FIG. 17 is a graph illustrating Young's modulus depending on a metal material of lines of FIG. 11;

FIG. 18 is a cross-sectional view illustrating an upper plastic layer on the lines of FIG. 11;

FIG. 19 is a cross-sectional view illustrating an example of an upper fixing layer of FIG. 13;

FIG. 20 is a cross-sectional view illustrating an example of a stretchable electronic device according to an embodiment of the inventive concept; and

FIG. 21 is a cross-sectional view illustrating an example of a stretchable electronic device according to an embodiment of the inventive concept.

### DETAILED DESCRIPTION

Embodiments of the present invention will be described in detail with reference to the accompanying drawings. Advantages and features of the present invention, and implementation methods thereof will be clarified through following embodiments described with reference to the accompanying drawings. The present invention may, however, be embodied in different forms and should not be construed as limited to the embodiments set forth herein. Rather, the embodiments introduced herein are provided so that the disclosed contents may be thorough and complete, and the spirit of the present invention may be sufficiently conveyed to those skilled in the art, and the present invention is only defined by the scope of the claims. Like reference numerals refer to like elements throughout.

In the following description, the technical terms are used only for explaining a specific embodiment while not limiting the present invention. In this specification, the terms of a singular form may include plural forms unless specifically mentioned. The meaning of ‘comprises’ and/or ‘comprising’ specifies a component, a step, an operation and/or an element does not exclude other components, steps, operations and/or elements. In addition, in the specification, a chip, a pad, a line, and an adhesive layer may be understood to mean mainly used in the semiconductor fields. Since it is according to a preferred embodiment, reference numerals presented in the order of description are not necessarily limited to the order.

The contents described above are specific examples for carrying out the embodiment of the inventive concept. The present disclosure will include not only the embodiments described above, but also embodiments that are changeable in design or easily changed. In addition, the present disclosure will also include technologies that are capable of being easily modified and implemented in the future using the foregoing embodiments.

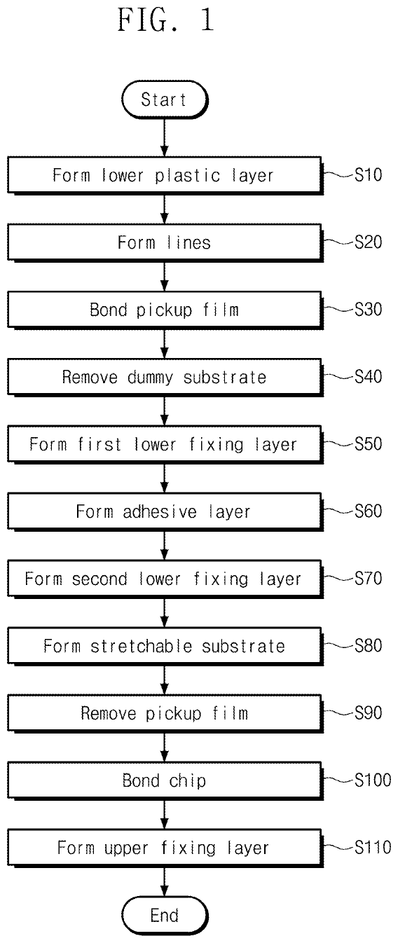

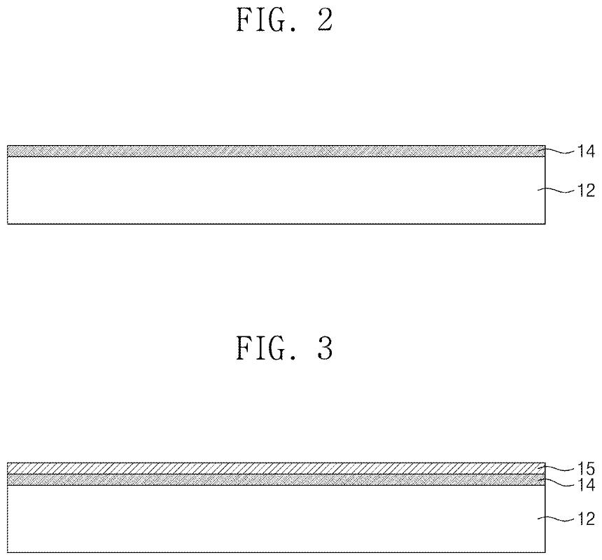

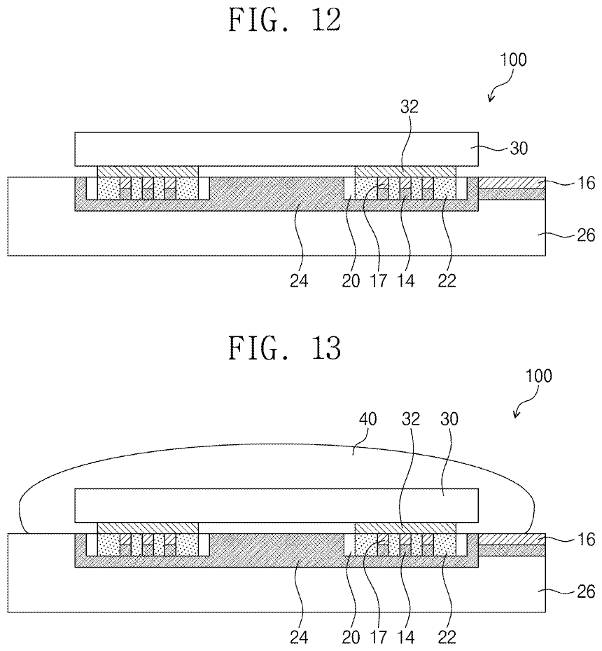

FIG. 1 is a flowchart illustrating a method for manufacturing a stretchable electronic device (reference numeral 100 of FIG. 12) according to an embodiment of the inventive concept. FIGS. 2 to 13 are cross-sectional view illustrating processes of the stretchable electronic device 100 according to an embodiment of the inventive concept.

Referring to FIGS. 1 and 2, a lower plastic layer 14 is formed on a dummy substrate 12 (S10). The lower plastic layer 14 may be a polyimide layer. For example, the lower plastic layer 14 may include photoresist. A thin film transistor (reference numeral 60 of FIG. 21) may be formed in the lower plastic layer 14. Alternatively, the thin film transistor 60 may be formed on the lower plastic layer 14, but the embodiment of the inventive concept is not limited thereto.

Referring to FIGS. 1, 3, and 4, lines 16 are formed on the lower plastic layer 14 (S20). The lines 16 may be formed through a deposition process, a photolithography process, and an etching process of the metal layer 15. For example, the metal layer 15 may include aluminum (Al), gold (Au), titanium (Ti), copper (Cu), nickel (Ni), chromium (Cr), and molybdenum (Mo), but the embodiment of the inventive concept is not limited thereto.

Referring to FIG. 3, the metal layer 15 may be deposited on the lower plastic layer 14. For example, the metal layer 15 may be deposited through a sputtering method or a metal evaporation method.

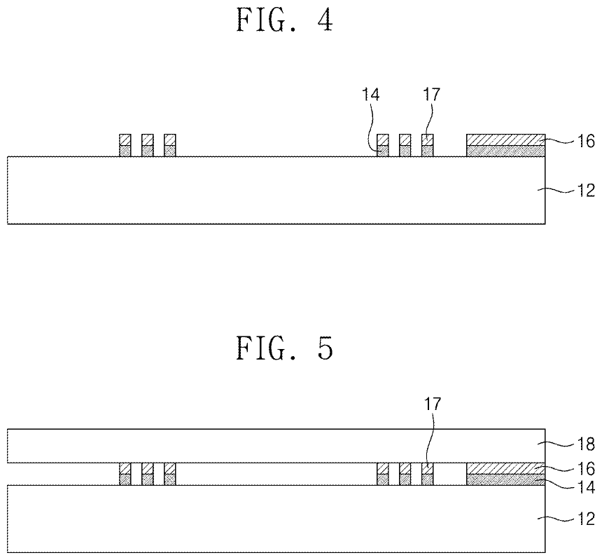

Referring to FIG. 4, the metal layer 15 may be patterned into lines 16 through the photolithography process and the etching process. The lower plastic layer 14 may be patterned to have the same shape as that of each of the lines 16.

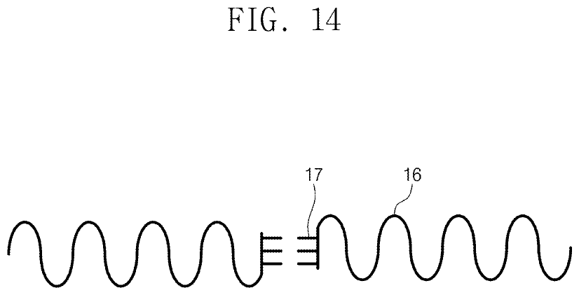

FIG. 14 is a plan view illustrating an example of the lines 16 of FIG. 4.

Referring to FIGS. 4 and 14, the lines 16 may have lower pads 17, respectively. The lower pads 17 may be provided on ends of the lines 16, respectively. Each of the lower pads 17 may have various shapes. For example, each of the lower pads 17 may have a rake shape. Although not shown, each of the lower pads 17 may have a circular shape, a rectangular shape, and a grid shape. Also, the lower pads 17 may include cut portions of the lines 16, but the embodiment of the inventive concept is not limited thereto.

The lines 16 may be meandered. When the lines 16 are stretched in a longitudinal direction thereof, the lines 16 may be changed to straight lines.

Referring to FIGS. 1 and 5, a pickup film 18 is bonded on the lines 16 (S30). The pickup film 18 may flatly bond the lines 16 to each other. For example, the pickup film 18 may include a polymer film such as vinyl.

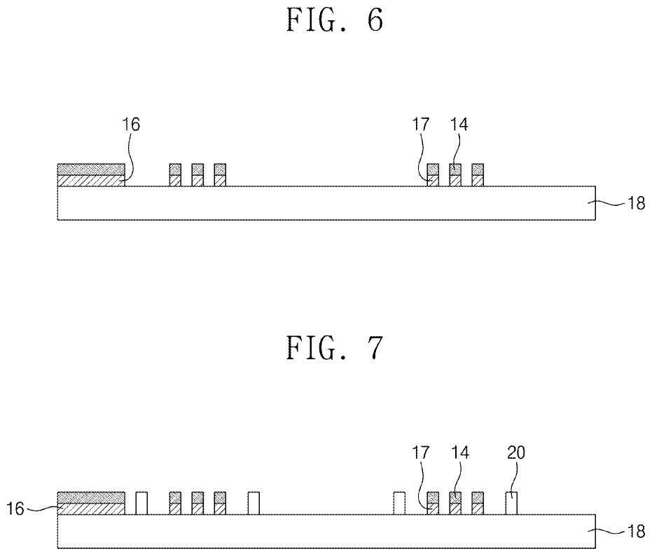

Referring to FIGS. 1 and 6, the dummy substrate 12 is removed (S40). The dummy substrate 12 may be removed by a laser-lift-off (LLO) method for the lower plastic layer 14. For example, the lower plastic layer 14 may be separated from the dummy substrate 12 by laser light transmitted to the dummy substrate 12.

Referring to FIGS. 1 and 7, a first lower fixing layer 20 is formed outside the lower pads 17 of the lines 16 (S50). The first lower fixing layer 20 may be provided to be spaced apart from the lower pads 17. Also, the first lower fixing layer 20 may be in contact with sidewalls of the lines 16. The first lower fixing layer 20 may be formed through a printing method. Alternatively, the first lower fixing layer 20 may be formed through a dripping method. The first lower fixing layer 20 may include polydimethylsiloxane (PDMS).

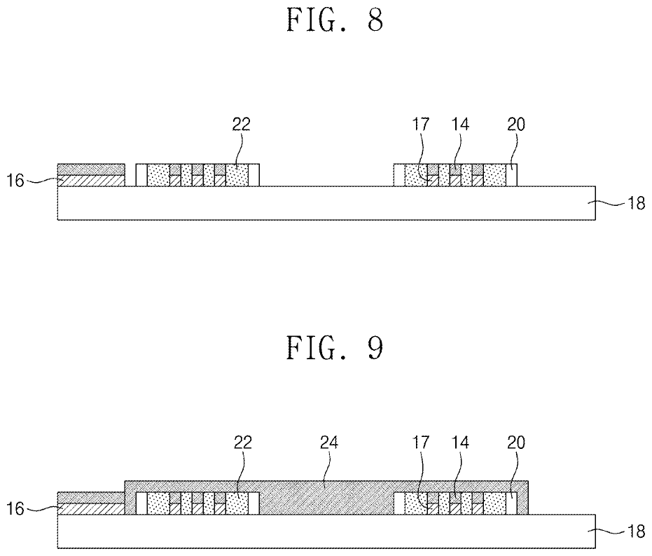

Referring to FIGS. 1 and 8, an adhesive layer 22 is formed in the first lower fixing layer 20 (S60). The adhesive layer 22 may be formed in the first lower fixing layer 20 surrounding the lower pads 17. The adhesive layer 22 may be formed through the dripping method or the printing method. The adhesive layer 22 may include a silicone compound. Alternatively, the adhesive layer 22 may include Ecoflex or Nusi.

Referring to FIGS. 1 and 9, a second lower fixing layer 24 is formed on the adhesive layer 22, the first lower fixing layer 20, and the lower plastic layer 14 (S70). The second lower fixing layer 24 may cover the adhesive layer 22, the first lower fixing layer 20, and the lower plastic layer 14. The second lower fixing layer 24 may be formed in the same manner as the first lower fixing layer 20. The second lower fixing layer 24 may be formed through the dripping method or the printing method. The second lower fixing layer 24 may include PDMS.

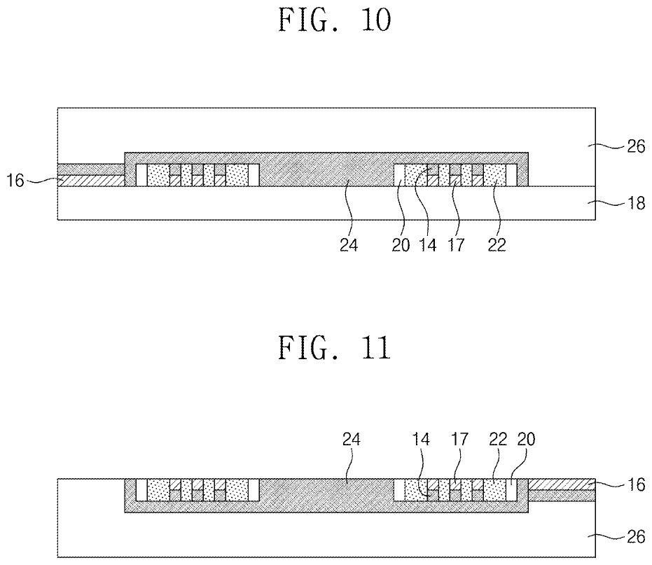

Referring to FIGS. 1 and 10, a stretchable substrate 26 is formed on the second lower fixing layer 24 (S80). The stretchable substrate 26 may be annealed after applying a source solution (not shown, for example, precursors) thereto. The stretchable substrate 26 may be thicker than each of the first lower fixing layer 20 and the second lower fixing layer 24. The stretchable substrate 26 may have higher flexibility and/or elasticity than each of the first lower fixing layer 20 and the second lower fixing layer 24. The stretchable substrate 26 may include a silicone compound having lower flexibility and/or elasticity than the adhesive layer 22. In addition, the stretchable substrate 26 may have low flexibility and/or elasticity similar to that of the adhesive layer 22, but the embodiment of the inventive concept is not limited thereto.

Referring to FIGS. 1 and 11, the pickup film 18 is removed (S90). For example, the pickup film 18 may be removed by a heat treatment process, but the embodiment of the inventive concept is not limited thereto. The lower plastic layer 14, the lines 16, the lower pads 17, the first lower fixing layer 20, and the second lower fixing layer 24 may be mounted in the stretchable substrate 26.

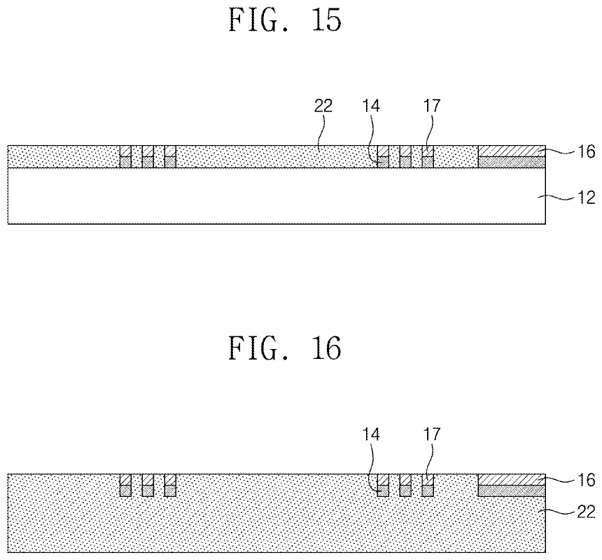

FIG. 15 is a cross-sectional view illustrating an example of the adhesive layer 22 of FIG. 11.

Referring to FIG. 15, the adhesive layer 22 may be formed on an entire top surface of the stretchable substrate 26 without the first lower fixing layer 20 and the second lower fixing layer 24. The lines 16 and the lower plastic layer 14 may be configured in the same manner as in FIGS. 4 to 11.

FIG. 16 is a cross-sectional view illustrating an example of the adhesive layer 22 of FIG. 11.

Referring to FIG. 16, the adhesive layer 22 may be used as a stretchable substrate in place of the first lower fixing layer 20, the second lower fixing layer 24, and the stretchable substrate 26 of FIG. 11. The adhesive layer 22 may be formed on bottom surfaces and sidewalls of the lines 16 and the lower plastic layer 14.

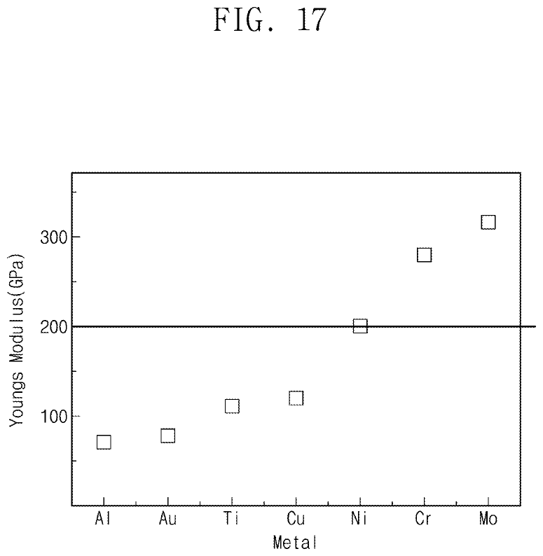

FIG. 17 is a graph illustrating Young's modulus depending on a metal material of the lines of FIG. 11.

Referring to FIG. 17, the lines 16 may have different Young's moduli depending on the metal material thereof. Each of the lines 16 may include aluminum (Al), gold (Au), and copper (Cu), which have a Young's modulus of less than about 200 GPa. For example, gold (Au) may have a Young's modulus of about 78.5 GPa, aluminum (Al) may have a Young's modulus of about 69 GPa, and copper (Cu) may have a Young's modulus of about 120 GPa. Nickel (Ni) may have a Young's modulus of about 200 GPa, chromium (Cr) may have a Young's modulus of about 260 GPa, and molybdenum (Mo) may have a Young's modulus of about 300 GPa.

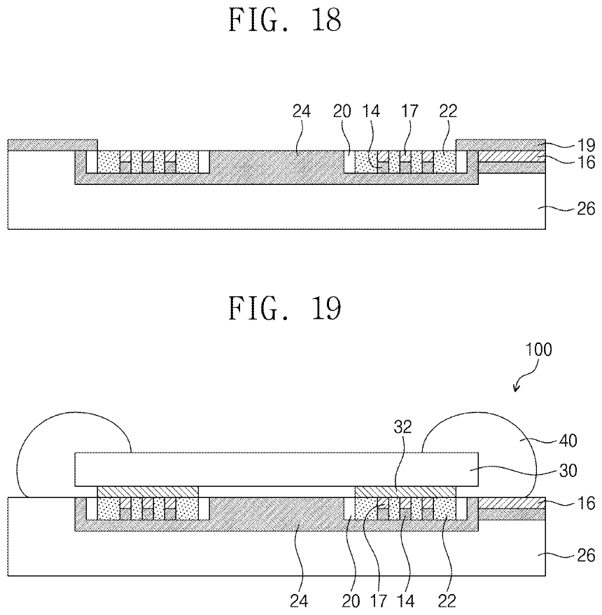

FIG. 18 is a cross-sectional view illustrating the upper plastic layer 19 on the lines of FIG. 11.

Referring to FIG. 18, when each of the lines 16 has a Young's modulus of about 200 GPa or more, the upper plastic layer 19 may be provided on the lines 16. When each of the lines 16 includes nickel (Ni), chromium (Cr), and molybdenum (Mo), the upper plastic layer 19 may be provided on the lines 16 to provide the lines 16. The upper plastic layer 19 may include the same material as that of the lower plastic layer 14. For example, the upper plastic layer 19 may include polyimide.

Referring to FIGS. 1 and 12, the chip 30 is bonded to the lines 16 (S100). The chip 30 may include a light emitting diode (LED). The chip 30 may have first upper pads 32. The first upper pads 32 may align and/or overlap the adhesive layer 22. The first upper pads 32 may be in contact with the lower pads 17 in the adhesive layer 22. The adhesive layer 22 may connect the lower pads 17 to the first upper pads 32. The adhesive layer 22 may facilitate attachment and detachment of the chip 30. Thus, in the stretchable electronic device 100 according to an embodiment of the inventive concept, the chip 30 may be easily replaced by using the adhesive layer 22.

The chip 30 may be detached from and attached to the adhesive layer 22 by user's external force. When the lifespan of the chip 30 expires, or defects occur in the chip 30, the user may separate the chip 30 from the adhesive layer 22 and replace the separated chip 30 with a new chip 30. The chip 30 may be easily replaced by the adhesive force of the adhesive layer 22 without a typical heat treatment or fusing process.

Additionally, an upper fixing layer 40 is formed on the chip 30 with reference to FIGS. 1 and 13 (S110). The upper fixing layer 40 may cover the chip 30. The upper fixing layer 40 may fix the chip 30 to the stretchable substrate 26. The upper fixing layer 40 may include a hard elastomer formed by the dripping method or the printing method. The upper fixing layer 40 may be transparent.

FIG. 19 is a cross-sectional view illustrating an example of the upper fixing layer 40 of FIG. 13.

Referring to FIG. 19, the upper fixing layer 40 may be formed on each of both edges of the chip 30. The upper fixing layer 40 may expose a center of the chip 30 and fix both the edges of the chip 30 to the stretchable substrate 26. The stretchable substrate 26, the lower plastic layer 14, the lines 16, the lower pads 17, the first lower fixing layer 20, the adhesive layer 22, the second lower fixing layer 24, the first upper pads 32, and the chip 30 may be configured in the same manner as in FIGS. 12 and 13.

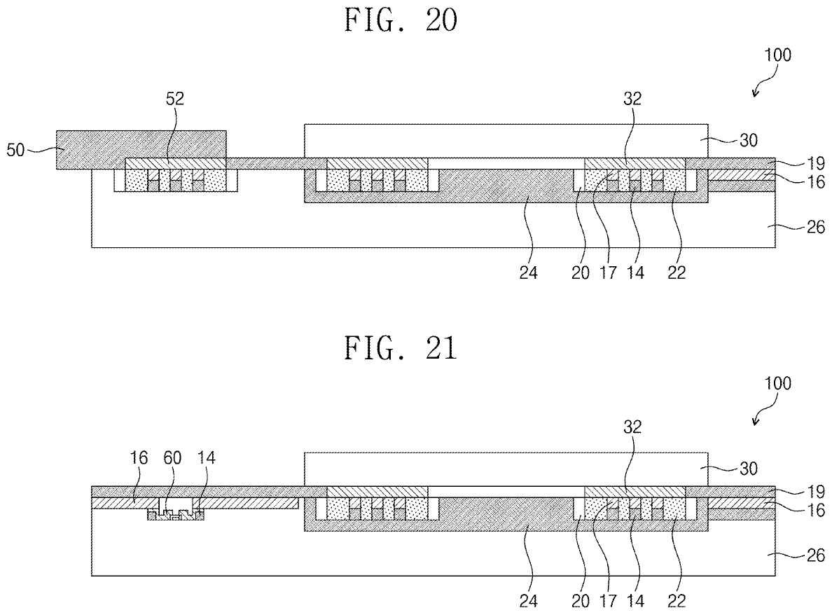

FIG. 20 is a cross-sectional view illustrating an example of a stretchable electronic device 100 according to an embodiment of the inventive concept.

Referring to FIG. 20, the stretchable electronic device 100 according to an embodiment of the inventive concept may further include a flexible printed circuit board 50 (FPCB). The flexible printed circuit board 50 may have a second upper pad 52. The second upper pad 52 may be provided on lower pads 17 and an adhesive layer 22. The second upper pad 52 may overlap the adhesive layer 22. The flexible printed circuit board 50 may connect a chip 30 to an external control circuit (not shown). In addition, the flexible printed circuit board 50 may connect the chip 30 to a power source (not shown), but the embodiment of the inventive concept is not limited thereto. A stretch substrate 26, a lower plastic layer 14, lines 16, a lower pads 17, a first lower fixing layer 20, a second lower fixing layer 24, first upper pads 32, and the chip 30 may be configured in the same manner as in FIG. 12.

FIG. 21 is a cross-sectional view illustrating an example of a stretchable electronic device 100 according to an embodiment of the inventive concept.

Referring to FIG. 21, a stretchable electronic device 100 according to an embodiment of the inventive concept may further include a thin film transistor 60. The thin film transistor 60 may be provided in a lower plastic layer 14. In addition, the thin film transistor 60 may be provided between the lower plastic layer 14 and lines 16. In addition, the thin film transistor 60 may be connected to the lines 16. The thin film transistor 60 may control a driving voltage applied to the chip 30. A stretchable substrate 26, a lower pads 17, a first lower fixing layer 20, an adhesive layer 22, a second lower fixing layer 24, first upper pads 32, and the chip 30 may be configured in the same manner as in FIG. 12.

As described above, the stretchable electronic device according to the embodiment of the inventive concept can easily realize the replacement of the chip using the adhesive layer bonded to the bottom surfaces of the upper pads of the chip.

In addition, in the method for manufacturing the stretchable electronic device, the chip may be fixed while being mounted to reduce the number of reflow processes by using the adhesive layer bonded to the bottom surfaces of the upper pads of the chip.

The contents described above are specific examples for carrying out the embodiment of the inventive concept. The present disclosure will include not only the embodiments described above, but also embodiments that are changeable in design or easily changed. In addition, the present disclosure will also include technologies that are capable of being easily modified and implemented in the future using the foregoing embodiments.

What is claimed is:

1. A stretchable electronic device comprising:
lines having lower pads;
a chip provided on the lower pads, the chip having first upper pads wider than the lower pads; and
an adhesive layer provided outside the lower pads or between the lower pads, the adhesive layer bonded to the first upper pads.

2. The stretchable electronic device of claim 1, further comprising a stretchable substrate in which the lines and the adhesive layer are mounted.

3. The stretchable electronic device of claim 2, further comprising a lower plastic layer provided in the stretchable substrate below the lines and the lower pads.

4. The stretchable electronic device of claim 3, further comprising a first lower fixing layer provided in the stretchable substrate to surround the adhesive layer, the lower pads, and the upper plastic layer.

5. The stretchable electronic device of claim 4, further comprising a second lower fixing layer configured to surround the first lower fixing layer and provided in the stretchable substrate.

6. The stretchable electronic device of claim 5, wherein each of the first lower fixing layer and the second lower fixing layer comprises PDMS.

7. The stretchable electronic device of claim 3, further comprising a thin film transistor provided in the lower plate layer and connected to the lines.

8. The stretchable electronic device of claim 2, wherein each of the stretchable substrate and the adhesive layer comprises a silicon compound.

9. The stretchable electronic device of claim 1, further comprising an upper fixing layer configured to cover the chip.

10. The stretchable electronic device of claim 1, further comprising a flexible printed circuit board disposed outside the chip, the flexible printed circuit board having second upper pads provided on the lower pads.

11. A stretchable electronic device comprising:
a stretchable substrate;
lines disposed on the stretchable substrate, the lines having lower pads;
a lower fixing layer configured to surround the lower pads and spaced apart from the lower pads;
an adhesive layer provided outside the lower pads or between the lower pads within the lower fixing layer; and
a chip having first upper pads aligned on the adhesive layer, the chip provided on the adhesive layer and the lower pads.

12. The stretchable electronic device of claim 11, further comprising
a thin film transistor provided in the lower plate layer and connected to the lines; and
a flexible printed circuit board having second upper pads aligned on the adhesive layer, the second upper pads provided on the lower pads.

13. A method for manufacturing a flexible electronic device, the method comprising:
forming lines having lower pads on a dummy substrate;
bonding a pickup film on the lines;
removing the dummy substrate;
forming an adhesive layer on the pickup film outside the lower pads;
removing the pickup film; and
bonding a chip having first upper pads, which are wider than the lower pads and bonded to the adhesive layer.

14. The method of claim 13, further comprising:
forming a first lower fixing layer on the pickup film between the lower pads and the adhesive layer; and
a second lower fixing layer on the first lower fixing layer and the adhesive layer.

15. The method of claim 14, further comprising forming a flexible substrate on the second lower fixing layer.

16. The method of claim 15, wherein each of the stretchable substrate and the adhesive layer comprises a silicon compound formed through a dripping method or printing method.

17. The method of claim 15, further comprising forming an upper fixing layer on the chip and the stretchable substrate outside the chip.

18. The method of claim 14, wherein each of the first lower fixing layer and the second lower fixing layer comprises PDMS formed through a printing method.

19. The method of claim 13, further comprising forming a lower plastic layer between the dummy substrate and the lines.

20. The method of claim 13, further comprising forming an upper plastic layer on the lines outside the adhesive layer.
